(19) United States
(12) Patent Application Publication
(10) Pub. No.: US 2026/0053075 A1
(43) Pub. Date: Feb. 19, 2026

(54) SUBSTRATE MOUNTING METHOD

(71) Applicant: Samsung Electronics Co., Ltd., Suwon-si (KR)

(72) Inventors: Tatsuya ISHIMOTO, Suwon-si (KR); Naoyuki TAKADA, Suwon-si (KR); Takahiro TOKUMIYA, Suwon-si (KR)

(73) Assignee: Samsung Electronics Co., Ltd., Suwon-si (KR)

(21) Appl. No.: 19/294,851

(22) Filed: Aug. 8, 2025

(30) Foreign Application Priority Data
Aug. 15, 2024 (JP) 2024-135547

(51) Int. Cl. H01L 21/50; H01L 21/67; H01L 21/683; H01L 21/78

(52) U.S. Cl. CPC H01L 21/50; H01L 21/67121; H01L 21/6836; H01L 21/78

(57) ABSTRACT

A substrate mounting method, performed by a mounting apparatus includes providing a stack including a substrate, a first protective member, and a second protective member, the first protective member being an outermost layer, cutting the stack to obtain at least one chip, removing the first protective member from the at least one chip, heating at least a portion of the second protective member, holding the at least one chip by attaching a bonding head of the mounting apparatus to the heated second protective member, and bonding the at least one chip to a base substrate using the bonding head.

### CROSS-REFERENCE TO RELATED APPLICATION(S)

This U.S. non-provisional application claims priority under 35 U.S.C. § 119 to Japanese Patent Application No. JP-2024-135547 filed on Aug. 15, 2024, the entire disclosure of which is incorporated herein by reference.

### BACKGROUND

Some example embodiments relate to a substrate mounting method.

In a semiconductor mounting process, an encapsulant is used to fill a gap formed between a chip and a wafer due to bumps formed to protrude from a chip surface. However, with the recent increase in demand for high-density mounting processes, a direct bonding method is used, which includes a die-to-wafer (D2 W) stacking technique for directly bonding device chips without using bumps.

The direct bonding method is performed by activating a chip surface serving as a bonding surface using plasma, or the like, to expose functional groups and bonding the functional groups to each other. Accordingly, the direct bonding method may reduce gaps caused by bumps and may allow the bonding target to be mounted more securely and with high density and reduced gaps.

In the direct bonding method, an activated surface is beneficial to have improved flatness and cleanliness. In the direct bonding method, chips are stacked one by one a plurality of times, and are bonded while being held with a bonding tool. In the direct bonding method, it may be challenging to reduce contamination of the chip surface even when the cleanliness of a working environment is increased. The chip surface may not be an activated surface and is used as a base for the next stacking. It may be difficult to reduce particles such as inorganic substances using water or other chemicals. Cleaning the chip surface using a mechanical cleaning method may increase risk of the chip breaking or peeling off.

### SUMMARY

Example embodiments are directed to a substrate mounting method to reduce contamination during a substrate mounting process.

According to some example embodiments, a substrate mounting method performed by a mounting apparatus includes providing a stack including a substrate, a first protective member, and a second protective member, the first protective member being an outermost layer of the stack, cutting the stack to obtain at least one chip, removing the first protective member from the at least one chip, heating at least a portion of the second protective member, holding the at least one chip by attaching a bonding head of the mounting apparatus to the heated second protective member, and bonding the at least one chip to a base substrate using the bonding head.

According to some example embodiments, a substrate mounting method includes providing a stack comprising a substrate and a protective member on a surface of the substrate, cutting the stack to obtain at least one chip including the substrate, heating the protective member, holding the at least one chip by attaching a bonding head to the heated protective member, and bonding the at least one chip to a base substrate using the bonding head.

According to some example embodiments, a substrate mounting method performed by a mounting apparatus including a bonding head includes providing a stack comprising a substrate having a first surface and a second surface opposite the first surface, a first protective member provided on the first surface of the substrate, and a second protective member provided on the second surface of the substrate, cutting the stack to obtain at least one chip, removing the first protective member from the at least one chip, heating an outer periphery of the second protective member, holding the at least one chip by attaching a bonding head to the heated second protective member, bonding the at least one chip to a base substrate using the bonding head, and removing the second protective member from the at least one chip after bonding the at least one chip to the base substrate. The first protective member and the second protective member are each removed using water, and one or more of the heating the outer periphery of the second protective member, the holding the at least one chip, and the bonding the at least one chip to the base substrate are repeated to sequentially stack a plurality of chips, the plurality of chips including the at least one chip.

### BRIEF DESCRIPTION OF DRAWINGS

The above and other aspects and features of the present disclosure will become more apparent by describing in detail example embodiments thereof with reference to the attached drawings, in which:

FIG. 1 is a flowchart illustrating a mounting method according to some example embodiments.

FIGS. 2A, 2B, 2C, 2D, 2E, 2F, 2G, 2H, 2I, 2J, and 2K are cross-sectional views illustrating operations in a mounting method of FIG. 1, according to some example embodiments.

FIG. 3 is a flowchart illustrating a mounting method according to some example embodiments.

FIGS. 4A, 4B, 4C, 4D, 4E, 4F, 4G, 4H, 4I, and 4J are cross-sectional views illustrating operations in a mounting method according to some example embodiments.

FIG. 5 is a flowchart illustrating a mounting method according to some example embodiments.

FIGS. 6A, 6B, 6C, 6D, 6E, 6F, 6G, 6H, 6I, and 6J are cross-sectional views illustrating operations in a mounting method of FIG. 5, according to some example embodiments.

FIGS. 7A, 7B, 7C, and 7D are cross-sectional views illustrating operations in a mounting method according to some example embodiments.

### DETAILED DESCRIPTION

Hereinafter, example embodiments will be described with reference to the accompanying drawings.

In the following drawings, the same reference numerals designate the same components and the size of each component may be exaggerated for clarity of illustration. Example embodiments described herein are for illustrative purpose only, and various modifications may be made therefrom.

Hereinafter, spatially relative terms “on,” “above,” or “upper” may refer not only to direct contact but also to a non-contact state relative to a reference object. Similarly, spatially relative terms “beneath,” “below,” or “lower” may refer to both direct contact and a non-contact state relative to a reference object.

A singular expression includes a plural expression, unless the context clearly states otherwise. In the present specification, it should be understood that the terms such as “include” or “have” are merely intended to indicate that features, numbers, steps, operations, components, parts, or combinations thereof are present, and are not intended to exclude the possibility that one or more other features, numbers, steps, operations, components, parts, or combinations thereof will be present or added.

Unless the order is clearly stated or there is a contrary explanation for the steps constituting the method, the steps may be performed in an appropriate order, and are not limited to the order of description of the steps. The use of all examples or exemplary terms is only for describing the technical idea, and unless limited by the claims, the scope is not limited by the examples or exemplary terms.

The terms such as “first” and “second” may be used to describe various components, but the components are not restricted by the terms. The terms are used only to distinguish one component from another component. For example, a first component may be named a second component without departing from the scope of the right of the present invention. Likewise, a second component may be named a first component.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

Hereinafter, the terms “lower portion” and “upper portion” are for convenience of description and do not limit the positional relationship.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., +10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

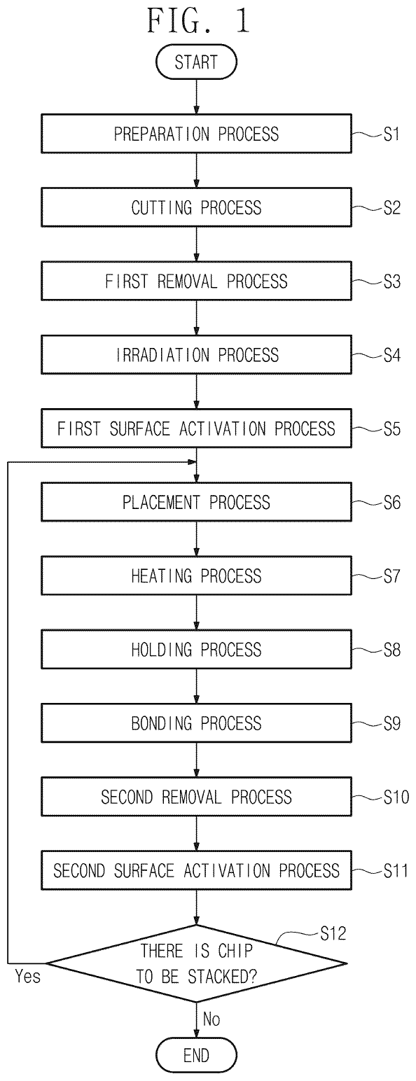

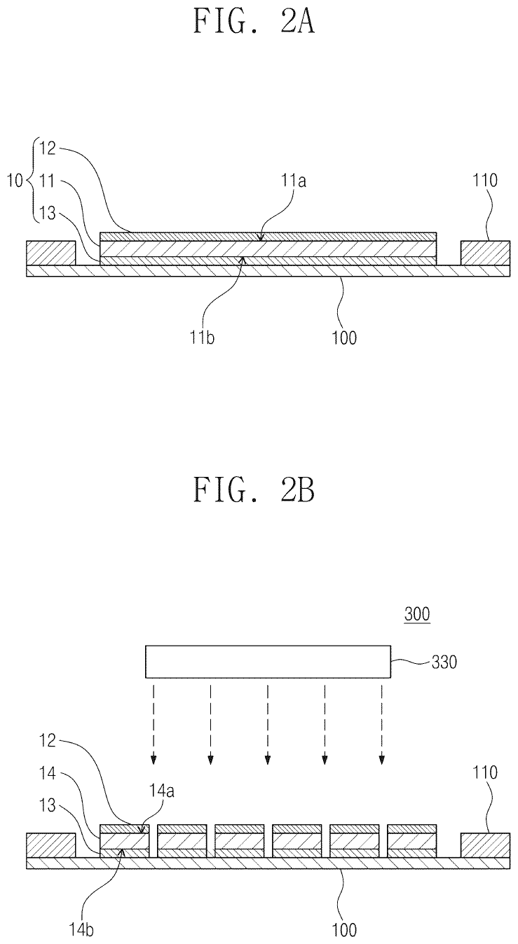

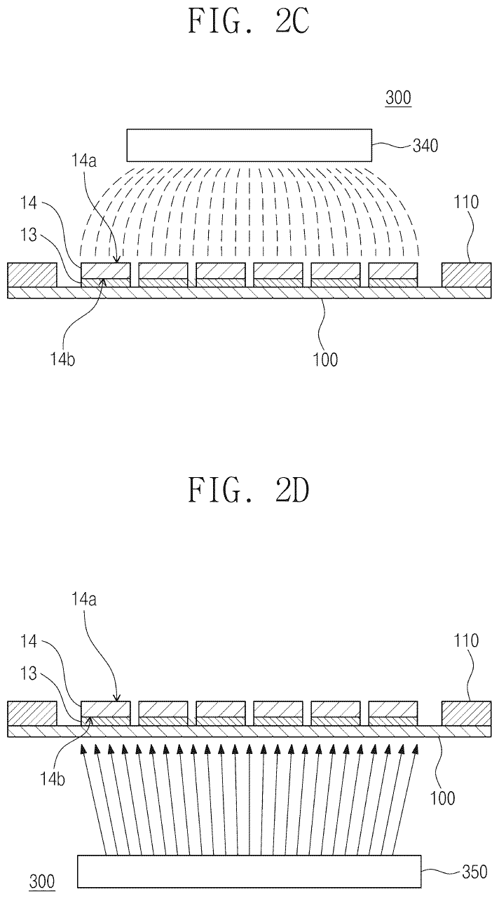

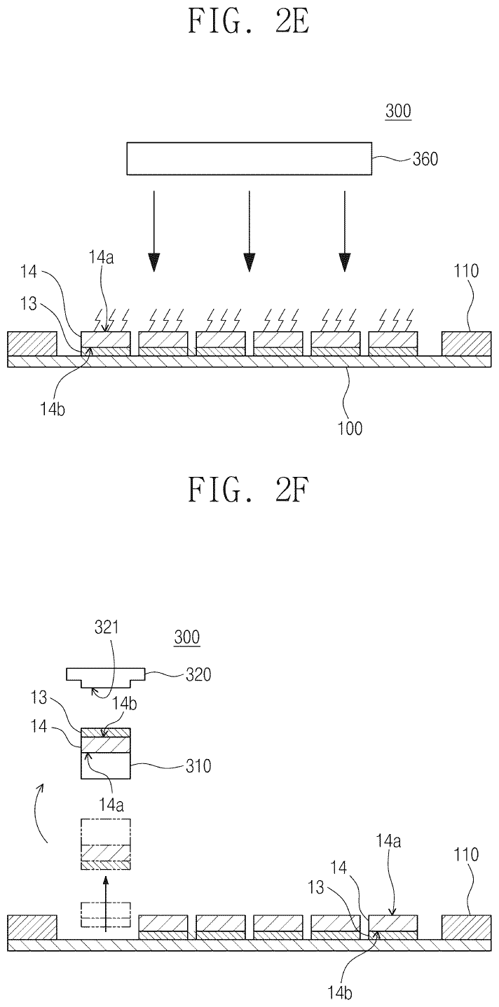

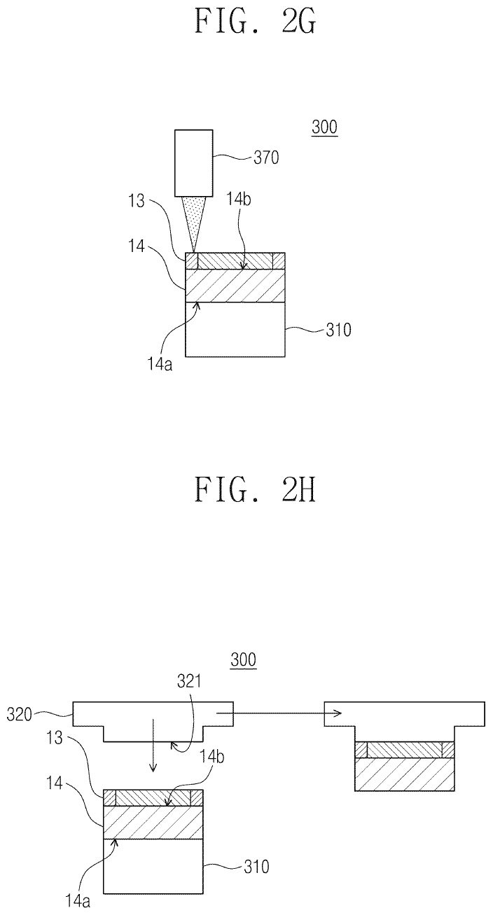

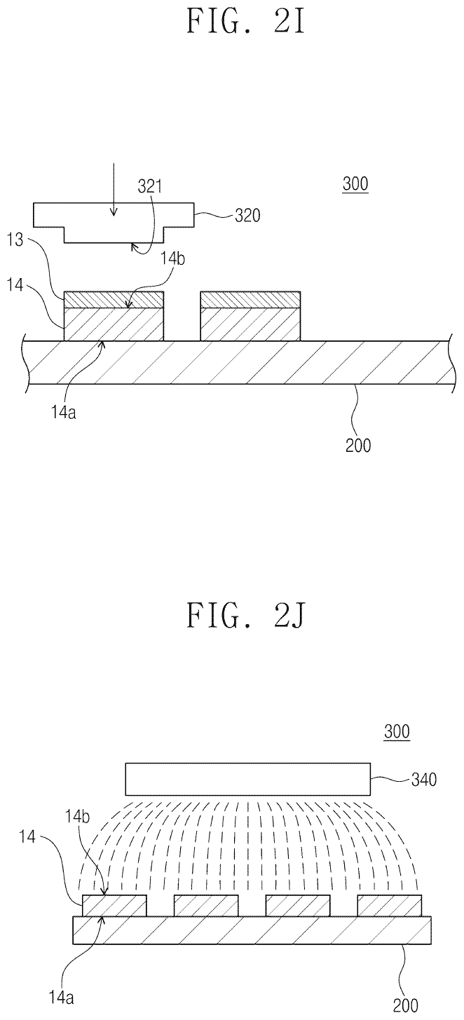

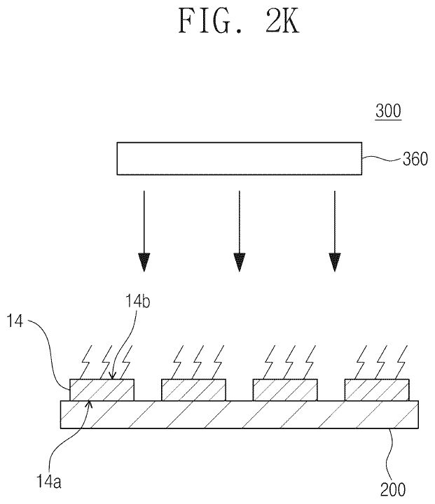

FIG. 1 is a flowchart illustrating a mounting method according to some example embodiments. FIGS. 2A to 2K are cross-sectional views illustrating operations in a mounting method according to some example embodiments. The mounting method in FIGS. 1 and 2A-2K, according to the example embodiments, may be referred to as “mounting method A.”

The mounting method according to some example embodiments may be a method applied to a mounting apparatus 300 that cuts a substrate 11, such as a wafer being processed into a device component such as a semiconductor chip or a substrate, to form individual chips 14, mounts the individual chips 14 on another base substrate 200, and/or stacks the chips 14 in multiple layers.

As illustrated in FIGS. 2B to 2H, the mounting apparatus 300 may include a pickup tool 310 (FIGS. 2F, 2H) picking up the chip 14 from a dicing tape 100, a bonding head 320 (FIGS. 2F, 2H, 2I) having a holding surface 321 for holding or securing the chip 14 picked up by the pickup tool 310, a cutting part 330 (FIG. 2B) cutting a stack 10, and a cleaning part 340 (FIG. 2C, 2J) cleaning the stack 10 or the chip 14, an irradiation part 350 (FIG. 2D) irradiating the stack 10 with active energy rays, a surface activation part 360 (FIGS. 2E, 2K) activating the first surface 14a of the chip 14, and a heating part 370 (FIG. 2G) heating at least a portion of the second protective member 13 of the chip 14. The mounting apparatus 300 may include all of the components, or may include some components as separate components apart from the mounting apparatus 300. In addition or alternatively, the mounting apparatus 300 may include a bonding stage and the base substrate 200 may be held or positioned on the bonding stage.

Referring to FIG. 1, a mounting method according to some example embodiments may include a providing process S1, a cutting process S2, a first removal process S3, an irradiation process S4, a first surface activation process S5, a placement process S6, a heating process S7, a holding process S8, a bonding process S9, a second removal process S10, and/or a second surface activation process S11. However, example embodiments are not limited thereto, and the mounting method may include other processes. It is understood that additional operations or processes can be provided before, during, and after the or processes in FIG. 1, and some of the operations described below can be replaced or eliminated, for additional embodiments of the method. The order of the operations or processes may be interchangeable, or two or more operations or processes can be performed simultaneously. In some example embodiments, the first surface activation process S5, the second removal process S10, and the second surface activation process S11 may be omitted.

Referring to FIG. 1 and FIGS. 2A to 2K, in the providing process (S1), a stack 10 may be provided. The stack 10 may include a substrate 11 and a protective member. The protective member may include a first protective member 12 and a second protective member 13. The stack 10 may have a stack structure in which the first protective member 12 is an outermost (or topmost) layer.

The stack 10 may have a structure in which the first protective member 12 is disposed on one surface of the substrate 11, and the second protective member 13 is disposed on the other surface opposite the one surface. The first protective member 12 may be disposed on the outermost (or topmost) layer of the stack 10. For example, the first protective member 12 may be disposed on the first surface 11a that is an upper (or top) surface of the substrate 11, and the second protective member 13 may be disposed on the second surface 11b that is a lower (or bottom) surface of the substrate 11. The stack 10 may be attached and/or fixed (or secured) to the dicing tape 100 fixed to a dicing frame 110.

The substrate 11 may be a wafer to be a semiconductor chip or a substrate. A constituent material of the wafer is not limited to any particular material provided it is material suitable for use in a semiconductor device, such as metal or resin. As illustrated in FIG. 2B, the substrate 11 may be cut in the cutting process S2 and then divided into a plurality of chips 14.

In the cutting process S2, the first protective member 12 may protect the first surface 11a of the substrate 11. The first protective member 12 may be removed in the first removal process S3. The first protective member 12 may include, for example, a material that may be removed by a cleaning agent such as water or alcohol. The first protective member 12 may include a water-soluble material that may be cleaned (or removed) with water in consideration of the handling properties of the cleaning agent and an impact on the chip 14. The first protective member 12 may include a sheet-shaped member configured for arrangement with the substrate 11. However, the first protective member 12 may include a film member formed by applying a liquid material to the substrate 11 and curing the applied liquid material. In the cutting process S2, when plasma dicing is performed, a dicing thickness may be set to, for example, 50 μm (or about 50 μm) or more such that selective activation by plasma may be possible.

The stack 10 may be formed by attaching the first protective member 12 to the substrate 11 and attaching the substrate 11 having the first protective member 12 to the second protective member 13 disposed on the dicing tape 100.

In the cutting process S2, the cutting part 330 (for example, a wafer sawing apparatus) may be driven or operated to cut the stack 10, as illustrated in FIG. 2B. The stack 10 may be cut to form a plurality of chips 14 each having a desired (or, alternatively predetermined) size. The cutting method in the cutting process S2 may vary depending on the substrate 11 to be cut. The cutting method may be, for example, a blade dicing method, a laser ablation method, or a plasma dicing method. The plasma dicing method may be a cutting method in which plasma is irradiated to cut a substrate while a mask, or the like, is removed by laser grooving.

In the first removal process S3, the cleaning part 340 (for example, a deionized water (DI) rinsing tool, a nano-spray, or other type of wet-processing cleaning tool) may be driven or operated, as illustrated in FIG. 2C, to remove the first protective member 12 provided on the first surface 14a of the chips 14. In the first removal process S3, when the first protective member 12 is a water-soluble material, cleaning may be performed with water. As a result, the first protective member 12 provided on the first surface 14a of the chips 14 and particles (or contaminants) attached to the vicinity of the chips 14 may be removed. The first removal process S3 may be performed, followed by stretching the dicing tape 100, to widen a gap between chips 14, allowing the individual chips 14 to be separated with relative ease.

In the irradiation process S4, the irradiation part 350 may be driven or operated and active energy rays (for example, IR radiation, UV radiation, x-rays) may be irradiated onto the dicing tape 100 and the second protective member 13, as illustrated in FIG. 2D. The active energy rays may change a composition of the adhesive of the dicing tape 100 and the adhesive force of the dicing tape 100 may be reduced by the irradiation with active energy rays, facilitating in the peeling of the individual chips 14. In addition, the second protective member 13 may change to a water-soluble state by the irradiation with active energy rays. In some example embodiments, the second protective member 13 may be a sheet-shaped member that changes to a water-soluble state by the irradiation with active energy rays.

In the first surface activation process S5, the surface activation part 360 may be driven or operated and a surface activation treatment may be performed to activate at least a portion of the surface of the chips 14, as illustrated in FIG. 2E. In the first surface activation process S5, the surface activation treatment may be performed on the entire first surface 14a of the chips 14, facilitating subsequent bonding with the base substrate 200 or the bonding with the second surface 14b of the chip 14 that is to be stacked. The surface activation treatment may be performed, for example, through a plasma treatment, a corona treatment, an ultraviolet treatment, or combinations thereof. The plasma treatment may include a process in which chemical bonds of molecules present on the first surface 14a of the chip 14 are cleaved or cut or separated by ions or electrons emitted by discharge, and hydroxyl groups (—OH), hydrophilic functional groups, are formed.

In the placement process S6, the chips 14 may be picked up from the dicing tape 100 by the pickup tool 310, as illustrated in FIG. 2F. Then, the chips 14 may be disposed or arranged such that the second protective member 13 faces toward the bonding head 320. The pickup tool 310 may be or include a wafer handling tool that may pick the individual chips 14 using vacuum or in another non-contact manner, and may rotate 180° the second protective member 13 provided on the second surface 14b of the chips 14 to face toward a holding surface 321 of the bonding head 320, which may vacuum adsorb the chip 14.

In the heating process S7, the heating part 370 may be driven or operated to heat at least a portion of the second protective member 13, as illustrated in FIG. 2G. For example, the heating of the second protective member 13 may be performed in a state in which the second protective member 13 is disposed to face toward the bonding head 320 or in a state in which the second protective member 13 is picked up to the vicinity of the bonding head 320 by the pickup tool 310. The second protective member 13 may be heated to improve both the adhesiveness of the second protective member 13 to the bonding head 320 and the holding capacity for the holding surface 321 of the bonding head 320.

The heating part 370 may heat at least a portion of the second protective member 13. The heating part 370 may be directly disposed or positioned on the bonding head 320 or may be disposed in the vicinity of the bonding head 320. For example, the heating part 370 may heat at least a portion of the second protective member 13 with the bonding head 320 interposed between the heating part 370 and the second protective member 13, or from the vicinity of the bonding head 320. The heating part 370 may be or include equipment for heating the second protective member 13, for example, a lamp or a laser irradiator. For example, the heating process S7 may be performed through either heating using a lamp or laser heating. When the heating part 370 is a laser irradiator, a heating area of the second protective member 13 may be predefined or set. Thus, the adhesiveness and adhesion area of the second protective member 13 may be appropriately controlled. In some example embodiments, the heating part 370 may heat only an outer periphery of the chip 14 in the second protective member 13. The adhesive strength of the second protective member 13 may be adequate enough to adhere or attach the chip 14 to the bonding head 320 such that the chip 14 remains attached and does not peel off during the subsequent processes. Accordingly, the chip 14 may adhere with relative ease to the bonding head 320 without peeling off until the bonding process S9. The pickup tool 310 may then be release the chip 14 after it has been attached to the bonding head 320.

In the holding process S8, the heated chip 14 may be held or positioned while being attached or secured to the holding surface 321 of the bonding head 320, as illustrated in FIG. 2H. Due to the heating process S7, the adhesiveness of the second protective member 13 increases, so that the chip 14 may be stably held or arranged without peeling off or detaching from the holding surface 321. The holding surface 321 may be a relatively smooth or even or polished surface such that adsorption marks do not remain on the first surface 14a of the chip 14 attached to the bonding head 320. Also, the order of the holding process S8 and the heating process S7 may be changed, or the holding process S8 and the heating process S7 may be performed simultaneously. In some example embodiments, the heating process S7 may be performed before the holding process S8 to limit the chip from peeling off from the holding surface 321.

In the bonding process S9, the chip 14 that is held or positioned on the bonding head 320 may be bonded to a base substrate 200, as illustrated in FIG. 2I. The base substrate 200 may be or include, for example, a printed circuit board (PCB) or a ceramic substrate. The first surface 14a of the chip 14 is activated in the first surface activation process S5, enabling firm or steady bonding to the base substrate 200. After the bonding is performed, the first surface 14a of the chip 14 may face toward the base substrate 200, while the second surface 14b may face the opposite direction.

In the second removal process S10, the cleaning part 340 is driven or operated to clean the chip 14 bonded to the base substrate 200, as illustrated in FIG. 2J. The second protective member 13 is changed to a water-soluble state in the irradiation process S4, so that the second protective member 13 and particles (or contaminants) attached to the vicinity of the chip 14 may be removed through water cleaning (or alternatively, may be removed using water).

In the second surface activation process S11, the surface activation part 360 is driven or operated to activate the second surface 14b of the chip 14 from which the second protective member 13 has been removed, as illustrated in FIG. 2K. Thus, the second surface 14b of the chip 14 may be firmly or securely bonded to the first surface 14a of the next (subsequent) chip 14 to be stacked in the next stacking cycle.

Then, the mounting apparatus 300 may perform the mounting process by sequentially repeating a procedure from the placement process S6 to the second surface activation process S11, as illustrated in FIGS. 2F to 2K, to stack a desired (or, alternatively predetermined) number of chips 14. For example, referring to process S12 illustrated in FIG. 1, the mounting apparatus 300 may check whether there is an additional chip 14 to be stacked in the next stacking cycle S12. When the mounting apparatus 300 determines that there is an additional chip 14 to be stacked in the next stacking cycle (S12—Yes), the flow returns to the placement process S6. When there is no chip 14 to be stacked in the next stacking cycle (S12—No), the mounting process is terminated.

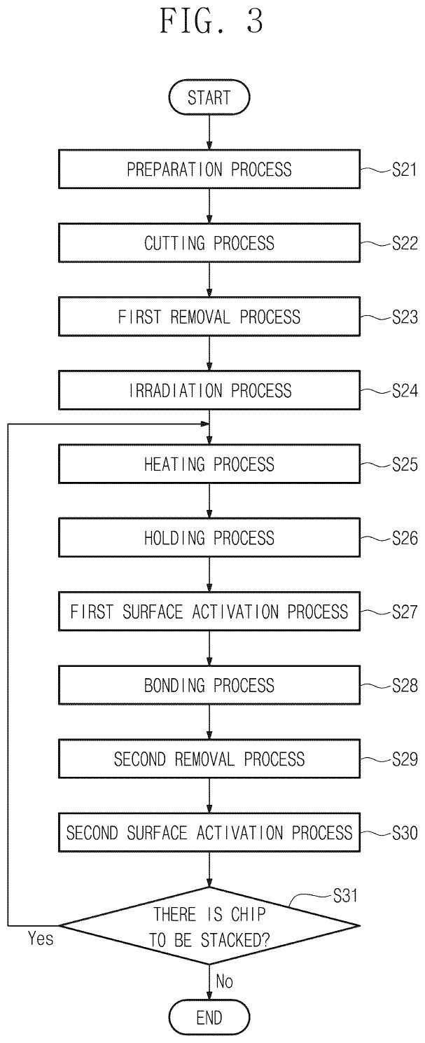

FIG. 3 is a flowchart illustrating a mounting method according to some example embodiments.

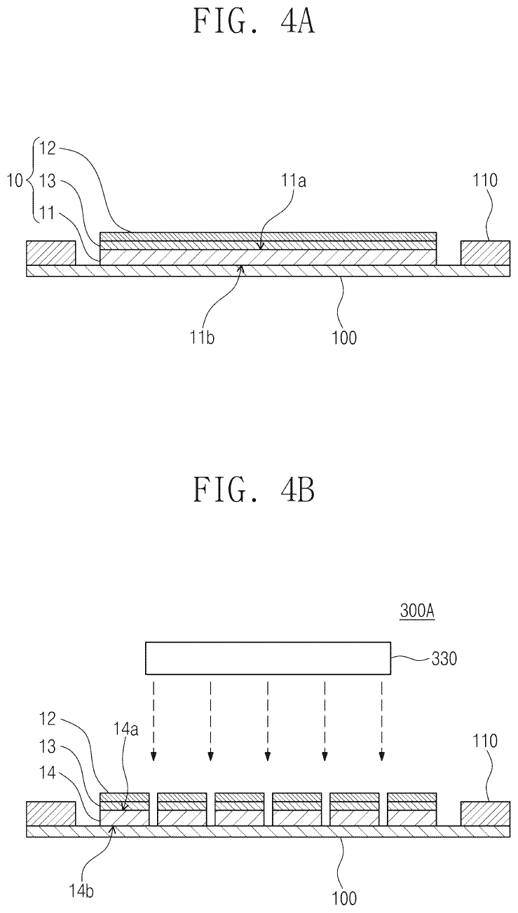

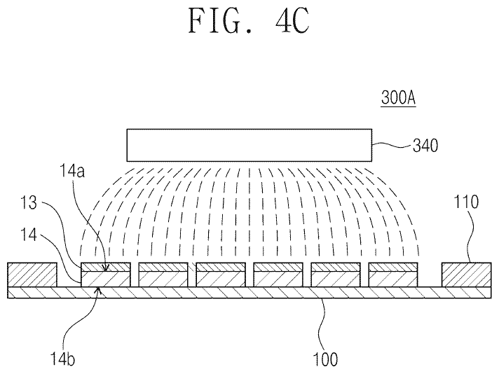

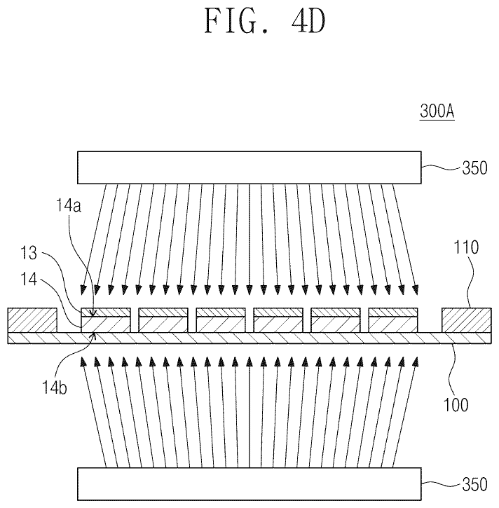

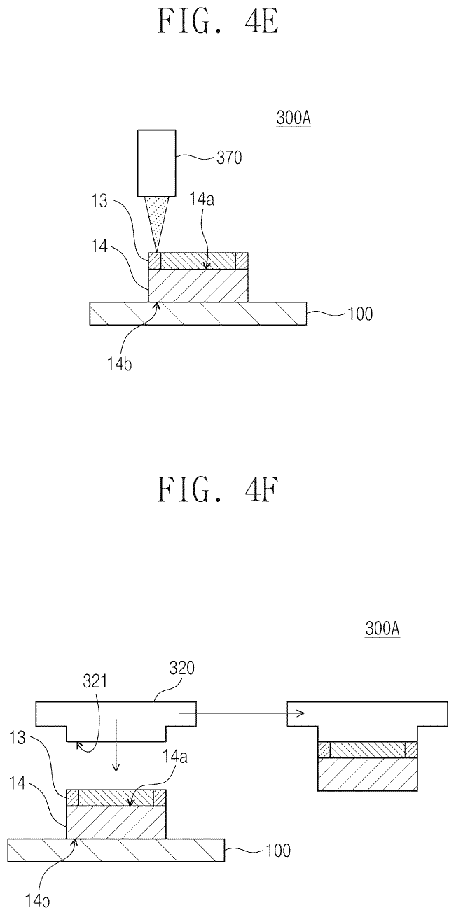

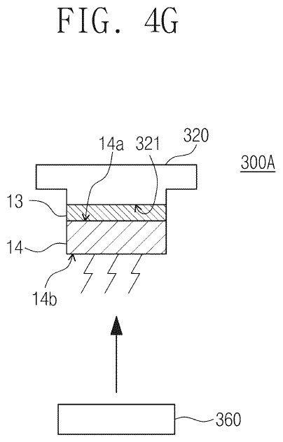

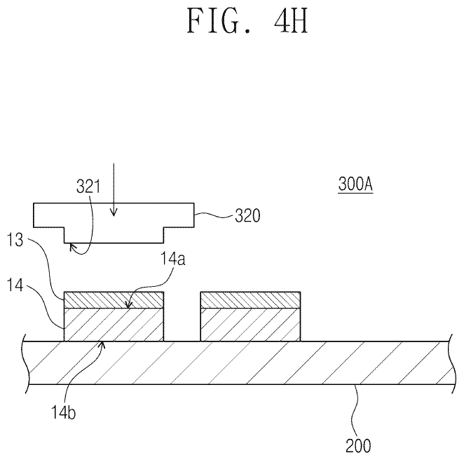

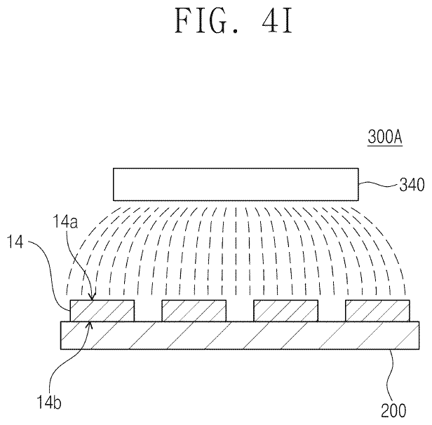

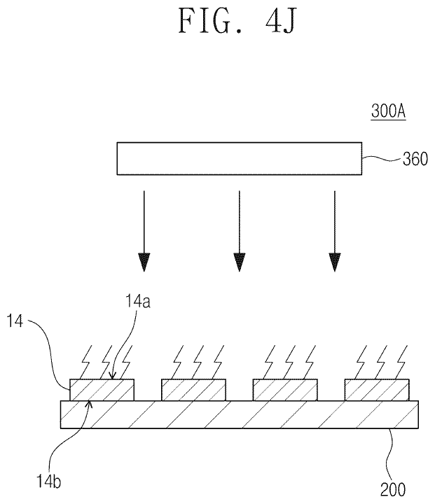

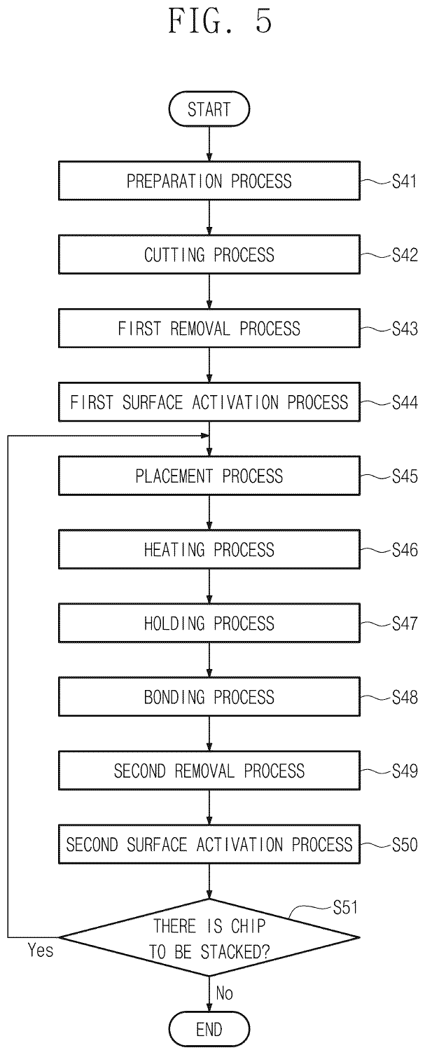

FIGS. 4A to 4J are cross-sectional views illustrating operations in a mounting method according to some example embodiments. The mounting method in FIGS. 3 and 4A to 4J, according to some example embodiments, described below may be referred to as “mounting method B.” The mounting method in FIGS. 3 and 4A to 4J may be same as or similar in some respects to the mounting method in FIGS. 1 and 2A-2K, and therefore may be best understood with reference thereto where like numerals indicate like elements not described again in detail.

Referring to FIG. 3, the mounting method according to some example embodiments may include a providing process S21, a cutting process S22, a first removal process S23, an irradiation process S24, a heating process S25, a holding process S26, a first surface activation process S27, a bonding process S28, a second removal process S29, and/or a second surface activation process S30. However, example embodiments are not limited thereto, and the mounting method may include other processes. In some example embodiments, the first surface activation process S27, the second removal process S29, and the second surface activation process S30 may be omitted. It is understood that additional operations or processes can be provided before, during, and after the processes in FIG. 3, and some of the operations described below can be replaced or eliminated, for additional embodiments of the method. The order of the operations or processes may be interchangeable, or two or more operations or processes can be performed simultaneously.

The mounting apparatus 300A performing the mounting method according to some example embodiments may omit the placement process S6 (see FIG. 1). Accordingly, the operation of the pickup tool 310 (see FIG. 2F) may be omitted.

Referring to FIG. 3 and FIGS. 4A to 4J, in the providing process S21, a stack 10 may be provided. The stack 10 may include a substrate 11, a first protective member 12, and a second protective member 13. The stack 10 may have a stack structure in which the first protective member 12 is an outermost or topmost layer.

As illustrated in FIG. 4A, the stack 10 may have a structure in which the first protective member 12 is disposed on one surface of the substrate 11, and the second protective member 13 is disposed between the substrate 11 and the first protective member 12. The first protective member 12 may be disposed on the outermost or topmost layer of the stack 10. For example, the second protective member 13 may be disposed on the first surface 11a that is an upper or top surface of the substrate 11, and the first protective member 12 may be stacked and disposed on the second protective member 13. The stack 10 may be attached and fixed to a dicing tape 100 fixed to a dicing frame 110.

In the cutting process S22, the cutting part 330 (for example, a wafer sawing apparatus) may be driven or operated to cut the stack 10 into a plurality of chips 14 each having a desired (or, alternatively predetermined) size, as illustrated in FIG. 4B.

In the first removal process S23, the cleaning part 340 may be driven or operated to remove the first protective member 12 provided on the first surface 14a of the chips 14, as illustrated in FIG. 4C. The first removal process S23 may be performed, followed by stretching the dicing tape 100, to widen a gap between the chips 14, allowing the individual chips 14 to be separated with relative ease.

In the irradiation process S24, the irradiation part 350 may be driven or operated and active energy rays may be irradiated to the dicing tape 100 and the second protective member 13, as illustrated in FIG. 4D.

In the heating process S25, the heating part 370 may be driven or operated to heat at least a portion of the second protective member 13, as illustrated in FIG. 4E.

In the holding process S26, the heated chip 14 may be attached to the holding surface 321 of the bonding head 320, as illustrated in FIG. 4F.

In the first surface activation process S27, the surface activation part 360 may be driven and a surface activation treatment may be performed to activate at least a portion of the surface of the chips 14, as illustrated in FIG. 4G. For example, the second surface 14b of the chip 14 may be activated.

In the bonding process S28, the chip 14 attached to the bonding head 320 may be bonded to a base substrate 200 via the second surface 14b of chip 14, as illustrated in FIG. 4H.

In the second removal process S29, the cleaning part 340 is driven or operated to clean the chip 14 bonded to the base substrate 200, as illustrated in FIG. 4I. During this process, the second protective member 13 and particles (or contaminants) attached to the vicinity of the chip 14 may be removed.

In the second surface activation process S30, the surface activation part 360 may be driven or operated to activate the first surface 14a of the chip 14 from which the second protective member 13 has been removed, as illustrated in FIG. 4J.

Then, the mounting apparatus 300A may perform the mounting process by sequentially repeating a procedure from the heating process S25 to the second surface activation process S30, as illustrated in FIGS. 4E to 4J, to stack a desired (or, alternatively predetermined) number of chips 14. For example, referring to step S31 illustrated in FIG. 1, the mounting apparatus 300A may check whether there is a subsequent chip 14 to be stacked in the next stacking cycle S31. When the mounting apparatus 300A determines that there is a subsequent chip 14 to be stacked in the next stacking cycle (S31—Yes), the flow returns to the heating process S5. When there is no chip 14 to be stacked in the next stacking cycle (S31—No), the mounting process is terminated.

FIG. 5 is a flowchart illustrating a mounting method according to some example embodiments.

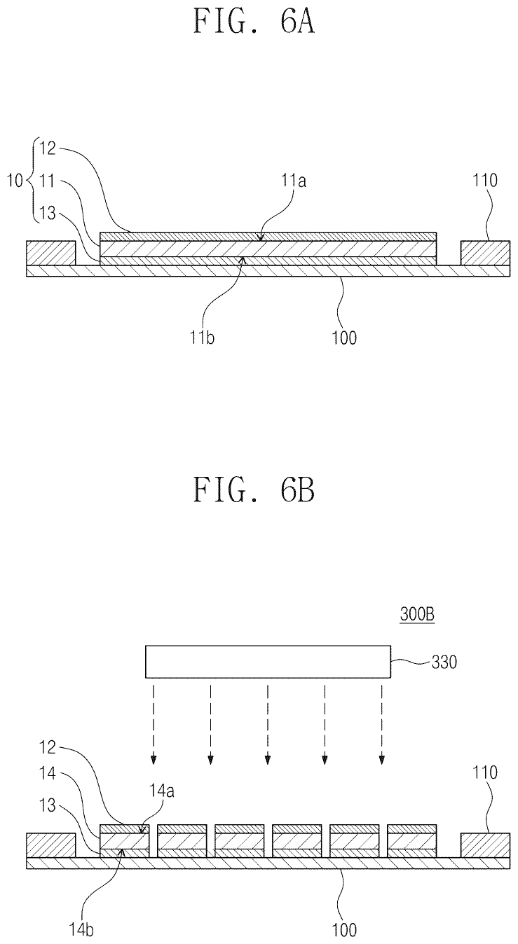

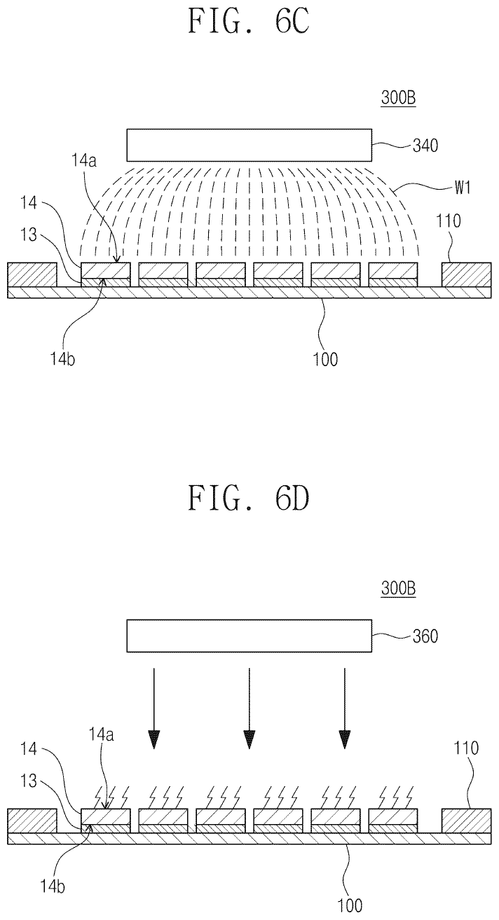

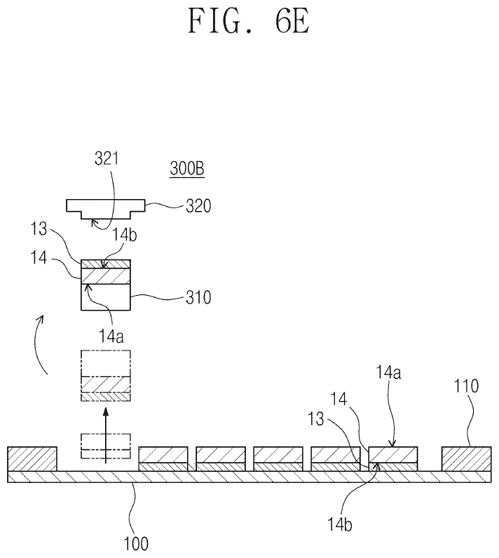

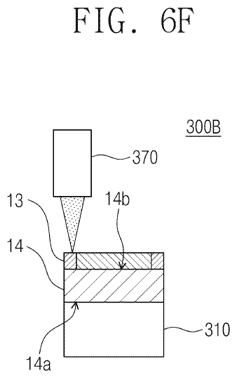

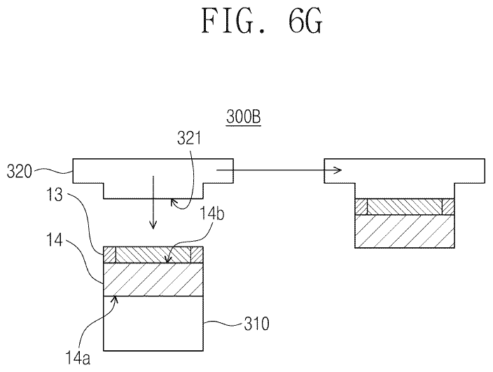

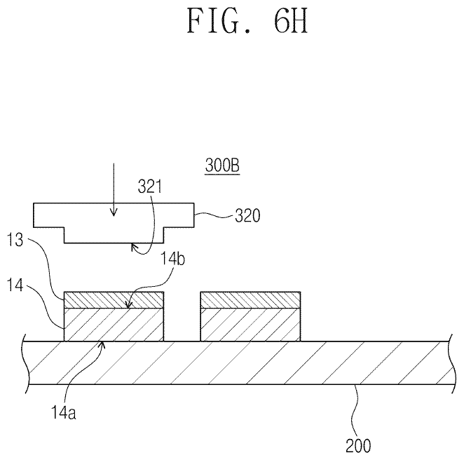

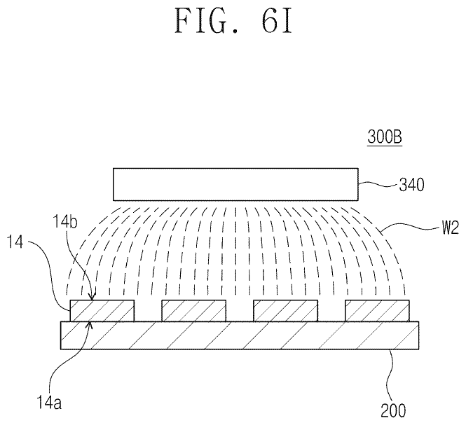

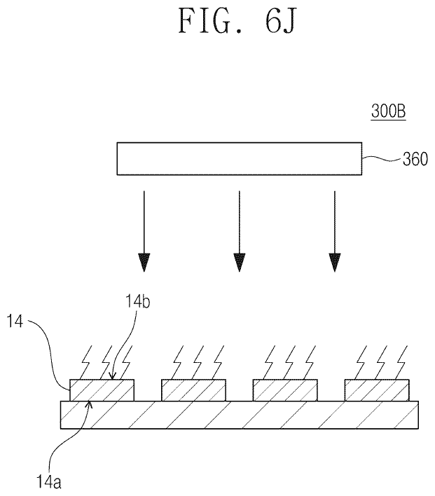

FIGS. 6A to 6J are cross-sectional views illustrating operations in a mounting method of FIG. 5 according to some example embodiments. The mounting method in FIGS. 5 and 6A to 6J, according to the example embodiments described below may be referred to as “mounting method C.” The mounting method in FIGS. 5 and 6A to 6J may be same as or similar in some respects to the mounting method in FIGS. 1 and 2A-2K and the mounting method in FIGS. 3 and 4A to 4J, and therefore may be best understood with reference thereto where like numerals indicate like elements not described again in detail.

Referring to FIG. 5, the mounting method according to some example embodiments may include a providing process S41, a cutting process S42, a first removal process S43, a first surface activation process S44, a placement process S45, a heating process S46, a holding process S47, a bonding process S48, a second removal process S49, and/or a second surface activation process S50. However, example embodiments are not limited thereto, and the mounting method may include other processes. In some example embodiments, the first surface activation process S44, the second removal process S49, and the second surface activation process S50 may be omitted. It is understood that additional operations or processes can be provided before, during, and after the processes in FIG. 5, and some of the operations described below can be replaced or eliminated, for additional embodiments of the method. The order of the operations or processes may be interchangeable, or two or more operations or processes can be performed simultaneously.

The cleaning part 340 of the mounting apparatus 300B used in the mounting method according to some example embodiments, which performs the first removal process S43 and the second removal process S49, may have a function of adjusting the water temperature during cleaning.

In addition, each of the first and second protective members 12 and 13 exhibits water solubility and may be dissolved at a predetermined dissolution temperature. The first protective member 12 may be formed of a material that dissolves at, for example, 50° C. (or about 50° C.) or less, and the second protective member 13 may be formed of a material that dissolves at, for example, 50° C. (or about 50° C.) or more. As a result, in the mounting method according to some example embodiments, the first protective member 12 may be selectively removed using water of 50° C. (or about 50° C.) or less in the first removal process S43, and the second protective member 13 may be selectively removed using water of 50° C. (or about 50° C.) or more in the second removal process S49.

In some example embodiments, the first protective member 12 and the second protective member 13 are dissolved and removed such that the first protective member 12 is dissolved and removed in the first removal process S43, and the second protective member 13 is dissolved and removed in the second removal process S49. Therefore, the dissolution temperature of the first protective member 12, the dissolution temperature of the second protective member 13, the temperature of the water used in the first removal process S43, and the temperature of the water used in the second removal process S49 are not limited to specific temperatures as long as they allow the above-described removal to be performed.

Referring to FIG. 5 and FIGS. 6A to 6J, in the providing process S41, the stack 10 may be provided. The stack 10 may include the substrate 11, the first protective member 12, and the second protective member 13. The stack 10 may have a stack structure in which the first protective member 12 is an outermost or topmost layer.

As illustrated in FIG. 6A, the stack 10 may have a structure in which the first protective member 12 is disposed on one surface of the substrate 11, and the second protective member 13 is disposed on the other surface opposite the one surface. The first protective member 12 may be disposed on the outermost or topmost layer of the stack 10. For example, the first protective member 12 may be disposed on the first surface 11a that is an upper or top surface of the substrate 11, and the second protective member 13 may be disposed on the second surface 11b that is a lower or bottom surface of the substrate 11. The stack 10 may be attached and fixed to a dicing tape 100 fixed to a dicing frame 110.

In the cutting process S42, the cutting part 330 (for example, a wafer sawing apparatus) may be driven or operated to cut the stack 10 into a plurality of chips 14 each having a desired (or, alternatively predetermined) size, as illustrated in FIG. 6B.

In the first removal process S43, the cleaning part 340 may be driven or operated to remove the first protective member 12 provided on the first surface 14a of the chips 14, as illustrated in FIG. 6C. In the first removal process S43, water W1 of 50° C. (or about 50° C.) or less may be used to selectively remove the first protective member 12. Accordingly, in some example embodiments, only the first protective member 12 on the chip 14 may be removed. The first removal process S43 may be performed, followed by stretching the dicing tape 100 to widen a gap between the chips 14, allowing the individual chips 14 to be separated with relative ease.

In the first surface activation process S44, the surface activation part 360 may be driven or operated and surface activation treatment may be performed to activate at least a portion of a surface of the chip 14, as illustrated in FIG. 6D. For example, at least a portion of a first surface 14a of the chip 14 may be activated.

In the placement process S45, the chip 14 may be picked up from the dicing tape 100 by a pickup tool 310, as illustrated in FIG. 6E. Accordingly, the chip 14 may be disposed such that the second protective member 13 faces toward the bonding head 320. The picking of the individual chips 14 may be performed in a non-contact manner, and the second protective member 13 provided on the second surface 14b of the chips 14 may be rotated 180° by the pickup tool 310 and disposed to face the holding surface 321 of the bonding head 320.

In the heating process S46, the heating part 370 may be driven or operated to heat at least a portion of the second protective member 13, as illustrated in FIG. 6F.

In the holding process S47, the heated chip 14 may be held or positioned while being attached to the holding surface 321 of the bonding head 320, as illustrated in FIG. 6G.

In the bonding process S48, the chip 14 held or positioned on the bonding head 320 and a base substrate 200 may be bonded, as illustrated in FIG. 6H.

In the second removal process S49, the cleaning part 340 may be driven or operated to clean the chip 14 bonded to the base substrate 200, as illustrated in FIG. 6I. In the second removal process S49, water W2 of 50° C. (or about 50° C.) or higher may be used to selectively remove the second protective member 13. Accordingly, the second protective member 13 provided on the second surface 14b of the chip 14 may be removed.

In the second surface activation process S50, the surface activation part 360 may be driven or operated to activate the second surface 14b of the chip 14 from which the second protective member 13 has been removed, as illustrated in FIG. 6J.

Then, the mounting apparatus 300B may perform the mounting process by sequentially repeating a procedure from the placement process S45 to the second surface activation process S50, as illustrated in FIGS. 6E to 6J, to stack a desired (or, alternatively predetermined) number of chips 14. For example, referring to process S51 illustrated in FIG. 5, the mounting apparatus 300B may check whether there is a subsequent chip 14 to be stacked in the next stacking cycle S51. When the mounting apparatus 300B determines that there is a subsequent chip 14 to be stacked in the next stacking cycle (S51—Yes), the flow returns to the placement process S45. When there is no chip 14 to be stacked in the next stacking cycle (S51—No), the mounting process is terminated.

Hereinafter, an example of the mounting method according to some example embodiments will be described.

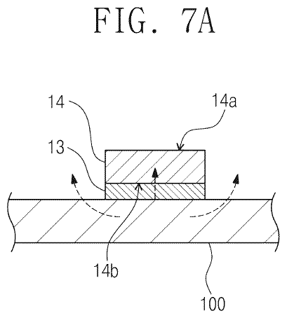

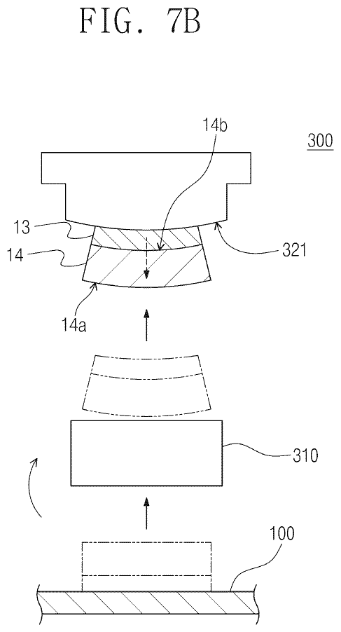

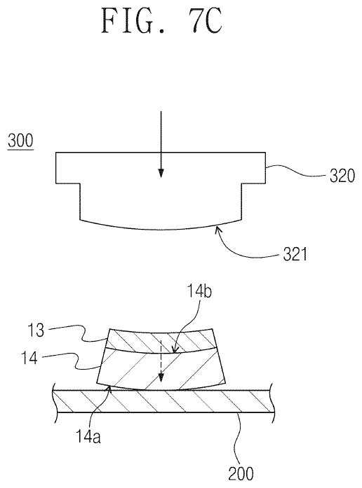

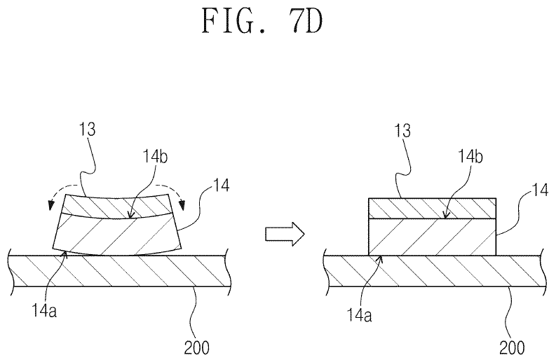

FIGS. 7A to 7D are cross-sectional views illustrating operations in a mounting method according to some example embodiments. The mounting method in FIGS. 7A to 7D may be same as or similar in some respects to the mounting method in FIGS. 1 and 2A-2K, the mounting method in FIGS. 3 and 4A to 4J, and the mounting method in FIGS. 5 and 6A to 6J, and therefore may be best understood with reference thereto where like numerals indicate like elements not described again in detail.

The mounting method in FIGS. 7A to 7D will be described with reference to the mounting method A, but it may also be equally applicable to the mounting method B or the mounting method C.

Referring to FIGS. 7A to 7D, a second protective member 13 may be rendered water-soluble by irradiation with active energy rays. In addition, the second protective member 13 may be designed to have a structure that increases bending stress that causes the entire chip 14 to be bent or flexed in a desired (or, alternatively specific) direction due to a force applied thereto.

As illustrated in FIG. 7A, the second protective member 13 may be subjected to bending stress (or force) that is applied on the entire chip 14 in such a way that a shape of the first surface 14a of the chip 14 is concave and a shape of the second surface 14b of the chip 14 is convex. The dotted arrows in FIG. 7A may indicate a direction of the bending stress to bend the chip 14. The second protective member 13 may be designed to be subjected to bending stress when irradiated with active energy rays.

In some example embodiments, the second protective member 13 may be subjected to bending stress (or force) applied on the chip 14 after the irradiation process S4 of the mounting method A. Also, the second protective member 13 may have bending stress to pre-bend the chip 14 in a desired (or, alternatively specific) direction.

The second protective member 13 may be disposed on the dicing tape 100 after the irradiation process S4, as illustrated in FIG. 7A. The bending stress may be reduced or suppressed by the adhesive force of the dicing tape 100. Accordingly, the chip 14 may hold a relatively flat shape without bending. The second protective member 13 may be released from the adhesive force of the dicing tape 100 when the chip 14 is picked up by the pickup tool 310. As a result, the chip 14 may be bent by the bending stress of the second protective member 13 in such a way that the first surface 14a is concave and the second surface 14b is convex.

The holding surface 321 of the bonding head 320 may have a convex shape conforming to a curved shape of the chip 14, as illustrated in FIG. 7B. Accordingly, when the chip 14 is transferred from the pickup tool 310 to the bonding head 320, the bonding head 320 may hold the chip 14 in a manner that conforms to the shape of the chip 14 in the holding process S8. Therefore, the chip 14 may be not detach or dislodge from the bonding head 320.

When the chip 14 is bonded to the base substrate 200 during the bonding process S9, the bending stress of the second protective member 13 may act on the chip 14, causing the first surface 14a of the chip 14 to be pressed against the base substrate 200. The chip 14 may be pressed against the base substrate 200 from the center of the first surface 14a toward an outer periphery due to the bending stress of the second protective member 13. In the bonding process S9, the chip 14 may be bonded to the base substrate 200 using the pressure from the bonding head 320 during the bonding process S9 and the bending stress of the second protective member 13. As a result, bonding defects of the chip 14 may reduced or lowered in the bonding process S9. The chip 14 may be bonded by the bonding head 320 and then bonded to the base substrate 200, as illustrated in FIG. 7D.

As set forth above, according to some example embodiment, a substrate mounting method that reduces contamination of particles (or contaminants) with minimally changing the mounting process, for example, from dicing process to bonding process, may be provided.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A substrate mounting method performed by a mounting apparatus, the method comprising:
providing a stack including a substrate, a first protective member, and a second protective member, the first protective member being an outermost layer of the stack;
cutting the stack to obtain at least one chip;
removing the first protective member from the at least one chip;
heating at least a portion of the second protective member;
holding the at least one chip by attaching a bonding head of the mounting apparatus to the heated second protective member; and
bonding the at least one chip to a base substrate using the bonding head.

2. The substrate mounting method of claim 1, wherein
the at least one chip includes a first surface and a second surface opposite the first surface,
the first protective member is on the first surface of the at least one chip and is water-soluble, and
the removing the first protective member comprises removing the first protective member by water cleaning.

3. The substrate mounting method of claim 2, further comprising:
removing the second protective member from the at least one chip after bonding the at least one chip to the base substrate.

4. The substrate mounting method of claim 3, further comprising:
irradiating the second protective member with energy rays to change the second protective member to be water-soluble, wherein
the second protective member is sheet-shaped and is changed to be water-soluble by irradiation with energy rays, and
removing the second protective member comprises removing the second protective member from the at least one chip using water after irradiating the second protective member.

5. The substrate mounting method of claim 4, further comprising: generating a bending stress in the second protective member by irradiating the second protective member with the energy rays.

6. The substrate mounting method of claim 3, wherein
the removing the first protective member comprises removing the first protective member from the first surface of the at least one chip with water having a first temperature, and
the removing the second protective member comprises removing the second protective member from the second surface of the at least one chip with water having a second temperature after bonding the at least one chip to a base substrate.

7. The substrate mounting method of claim 1, wherein
the heating at least the portion of the second protective member includes heating the second protective member by either laser heating or by a lamp, and
the heating heats at least a portion of the second protective member.

8. The substrate mounting method of claim 1, wherein
a holding surface of the bonding head is an even surface.

9. The substrate mounting method of claim 1, wherein
the substrate is a wafer for a semiconductor chip.

10. The substrate mounting method of claim 1, further comprising:
placing the at least one chip such that the second protective member of the at least one chip faces toward the bonding head after removing the first protective member.

11. The substrate mounting method of claim 1, wherein
the substrate has a first surface and a second surface opposite the first surface,
the first protective member is on the first surface of the substrate, and
the second protective member is on the second surface of the substrate.

12. The substrate mounting method of claim 1, wherein
the substrate has a first surface and a second surface opposite the first surface,
the first protective member is on the first surface of the substrate, and
the first protective member is on the second protective member.

13. The substrate mounting method of claim 1, wherein
the heating at least the portion of the second protective member includes heating at least the portion of the second protective member using laser heating or a lamp, and
the heating at least the portion of the second protective member includes heating an outer periphery of the second protective member.

14. The substrate mounting method of claim 1, further comprising:
performing at least one of a plasma treatment, a corona treatment, or an ultraviolet treatment on at least a portion of a surface of the at least one chip.

15. The substrate mounting method of claim 1, wherein
one or more of the heating at least a portion of the second protective member, the holding the at least one chip, and the bonding the at least one chip to a base substrate are repeated to sequentially stack a plurality of chips, the plurality of chips including the at least one chip.

16. A substrate mounting method, comprising:
providing a stack comprising a substrate and a protective member on a surface of the substrate;
cutting the stack to obtain at least one chip including the substrate;
heating the protective member;
holding the at least one chip by attaching a bonding head to the heated protective member; and
bonding the at least one chip to a base substrate using the bonding head.

17. The substrate mounting method of claim 16, further comprising:
removing the protective member from the at least one chip after the bonding, wherein
the removing of the protective member is performed by water cleaning.

18. The substrate mounting method of claim 16, wherein
the heating comprises heating an outer periphery the protective member.

19. The substrate mounting method of claim 16, further comprising:
irradiating the protective member with energy rays to change the protective member to be water-soluble.

20. A substrate mounting method performed by a mounting apparatus comprising a bonding head, the substrate mounting method comprising:
providing a stack comprising a substrate having a first surface and a second surface opposite the first surface, a first protective member provided on the first surface of the substrate, and a second protective member provided on the second surface of the substrate;
cutting the stack to obtain at least one chip;
removing the first protective member from the at least one chip;
heating an outer periphery of the second protective member;
holding the at least one chip by attaching a bonding head to the heated second protective member;
bonding the at least one chip to a base substrate using the bonding head; and
removing the second protective member from the at least one chip after bonding the at least one chip to the base substrate, wherein
the first protective member and the second protective member are each removed using water, and
one or more of the heating the outer periphery of the second protective member, the holding the at least one chip, and the bonding the at least one chip to the base substrate are repeated to sequentially stack a plurality of chips, the plurality of chips including the at least one chip.
